(19) United States
(12) Patent Application Publication
(10) Pub. No.: US 2018/0233433 A1
(43) Pub. Date: Aug. 16, 2018

(54) FAN-OUT SEMICONDUCTOR PACKAGE AND METHOD OF MANUFACTURING THE SAME

(71) Applicant: SAMSUNG ELECTRO-MECHANICS CO., LTD., Suwon-Si (KR)

(72) Inventors: Yoon Su KIM, Suwon-Si (KR); Seung Min BAEK, Suwon-Si (KR); Young Gwan KO, Suwon-Si (KR)

(21) Appl. No.: 15/948,535

(22) Filed: Apr. 9, 2018

Related U.S. Application Data
(63) Continuation of application No. 15/335,120, filed on Oct. 26, 2016.

(30) Foreign Application Priority Data
Nov. 26, 2015 (KR) 10-2015-0166305

(51) Int. Cl. H01L 23/485; H01L 23/498; H01L 23/00; H01L 21/48; H01L 23/482; H01L 25/10

(52) U.S. Cl. CPC H01L 23/485; H01L 2224/12105; H01L 24/19; H01L 21/486; H01L 21/4857; H01L 23/4827; H01L 24/20; H01L 23/49827; H01L 2224/73204; H01L 2225/1058; H01L 2924/37001; H01L 2224/04105; H01L 24/16; H01L 24/13; H01L 2225/1035; H01L 2224/16227; H01L 2924/15311; H01L 2924/3025; H01L 2224/131; H01L 2225/1041; H01L 2924/18162; H01L 2224/32225; H01L 24/32; H01L 25/105; H01L 24/73; H01L 23/49816

(57) ABSTRACT

A fan-out semiconductor package includes a semiconductor chip including a body and an electrode pad disposed on the body, a metal layer disposed on the electrode pad of the semiconductor chip, and a interconnection member including an insulating layer disposed on one side of the semiconductor chip, a via hole penetrating through the insulating layer and exposing at least a portion of a surface of the metal layer, a seed layer disposed on the surface of the metal layer exposed by the via hole and a wall of the via hole, and a conductor layer disposed on the seed layer.

### CROSS-REFERENCE TO RELATED APPLICATION

This application is a continuation of U.S. patent application Ser. No. 15/335,120, filed on Oct. 26, 2016, which claims benefit of priority to Korean Patent Application No. 10-2015-0166305 filed on Nov. 26, 2015, with the Korean Intellectual Property Office, the disclosure of which are incorporated herein by reference.

### TECHNICAL FIELD

The present disclosure relates to a fan-out semiconductor package and a method of manufacturing the same.

### BACKGROUND

a semiconductor package is a type of package technology for electrically connecting an electronic component to a printed circuit board (PCB), for example, a main board of an electronic device, or the like, and protecting the electronic component from external impacts.

Recently, one of the main trends in the development of technology related to electronic components is reducing electronic components in size. Therefore, in a package field, in accordance with a rapid increase in demand for small electronic components, or the like, the provision of a semiconductor package having a small size and including a plurality of pins has been demanded. In accordance with the technical demand described above, recently, a pattern and a via of an interconnection member used to carry out a redistribution function of the electronic component have been finely formed.

In the semiconductor package technology, reliability of the via of the interconnection member has recently become important. In a case in which the via of the interconnection member provided for the purpose of redistribution of the electronic component, particularly, a via connected to an electrode pad of the electronic component, is exposed to a harsh environment, stress applied to a connection terminal, for example, a solder ball, or the like, is concentrated on the via, such that a thermal cycle (TC) failure such as a crack, interfacial delamination, or the like, may occur.

### SUMMARY

An aspect of the present disclosure may provide a novel electronic component package in which reliability of a via of an interconnection member is improved, and a method of manufacturing the same.

According to an aspect of the present disclosure, a metal layer may be interposed between an electrode pad of an electronic component and a via of an interconnection member connected to the electrode pad.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on an interposer substrate and is finally mounted on a main board of an electronic device;

FIG. 6 is a schematic cross-sectional view illustrating a case in which a fan-in semiconductor package is embedded in an interposer substrate and is finally mounted on a main board of an electronic device;

FIG. 7 is a schematic cross-sectional view illustrating a fan-out semiconductor package;

FIG. 8 is a schematic cross-sectional view illustrating a case in which a fan-out semiconductor package is mounted on a main board of an electronic device

FIG. 9 is a cross-sectional view schematically illustrating an example of a fan-out semiconductor package;

FIG. 10 is a schematic enlarged view of region A of the fan-out semiconductor package of FIG. 9;

FIG. 11 is a view schematically illustrating an example of processes of manufacturing region A of the fan-out semiconductor package of FIG. 10;

FIGS. 12A through 12C are views schematically illustrating modified examples of region A of the fan-out semiconductor package of FIG. 10;

FIG. 13 is a cross-sectional view schematically illustrating another example of a fan-out semiconductor package;

FIG. 14 is a schematic enlarged view of region B of the fan-out semiconductor package of FIG. 13;

FIG. 15 is a view schematically illustrating an example of processes of manufacturing region B of the fan-out semiconductor package of FIG. 14;

FIGS. 16A through 16C are views schematically illustrating modified examples of region B of the fan-out semiconductor package of FIG. 14;

FIG. 17 is a cross-sectional view schematically illustrating another example of a fan-out semiconductor package;

FIG. 18 is a schematic enlarged view of region C of the fan-out semiconductor package of FIG. 17;

FIG. 19 is a view schematically illustrating an example of processes of manufacturing region C of the fan-out semiconductor package of FIG. 18;

FIGS. 20A through 20C are views schematically illustrating modified examples of region C of the fan-out semiconductor package of FIG. 18;

FIG. 21 is a cross-sectional view schematically illustrating another example of a fan-out semiconductor package;

FIG. 22 is a cross-sectional view schematically illustrating another example of a fan-out semiconductor package;

FIG. 23 is a cross-sectional view schematically illustrating another example of a fan-out semiconductor package;

FIG. 24 is a cross-sectional view schematically illustrating another example of a fan-out semiconductor package;

FIG. 25 is a cross-sectional view schematically illustrating another example of a fan-out semiconductor package;

FIG. 26 is a cross-sectional view schematically illustrating another example of a fan-out semiconductor package;

FIG. 27 is a view schematically illustrating a case in which a crack is generated between an electrode pad of an electronic component and a via of an interconnection member;

FIG. 28 is a view schematically illustrating a case in which an organic etching material remains on a surface of an electrode pad of an electronic component; and

FIG. 29 is a photograph of microstructures of copper (Cu) layers formed by electroplating and sputtering.

### DETAILED DESCRIPTION

Hereinafter, embodiments of the present inventive concept will be described as follows with reference to the attached drawings.

The present inventive concept may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein is for describing particular embodiments only and is not intended to be limiting of the present inventive concept. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present inventive concept will be described with reference to schematic views illustrating embodiments of the present inventive concept. In the drawings, for example, due to manufacturing techniques and/or tolerances, modifications of the shape shown may be estimated. Thus, embodiments of the present inventive concept should not be construed as being limited to the particular shapes of regions shown herein, for example, to include a change in shape results in manufacturing. The following embodiments may also be constituted by one or a combination thereof.

The contents of the present inventive concept described below may have a variety of configurations and propose only a required configuration herein, but are not limited thereto.

Electronic Device

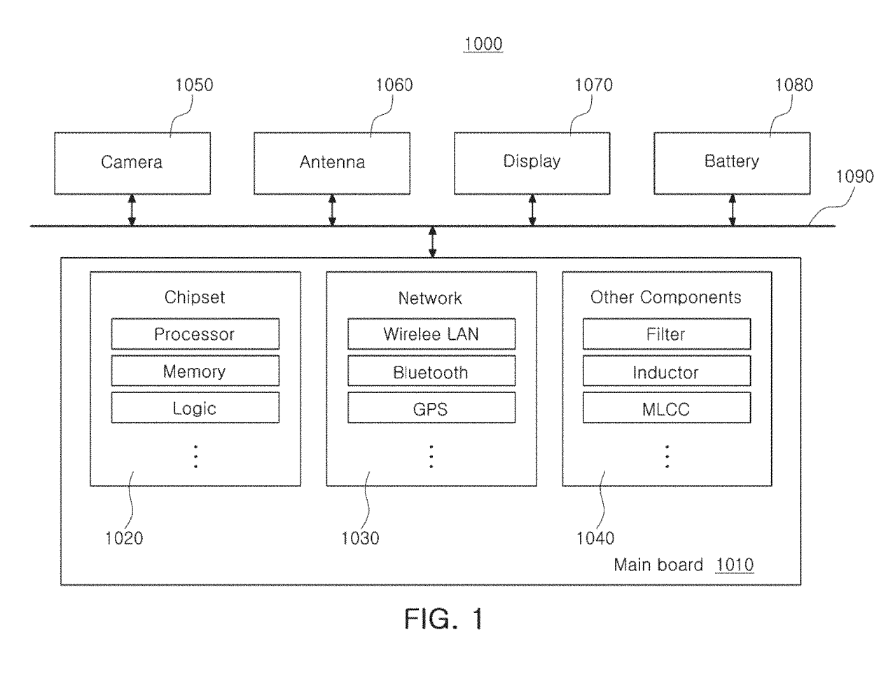

FIG. 1 is a schematic block diagram illustrating an example of an electronic device system;

Referring to FIG. 1, an electronic device 1000 may accommodate a main board 1010 therein. Chip related components 1020, network related components 1030, other components 1040, and the like, may be physically and/or electrically connected to the main board 1010. These components may be connected to other component to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphic processor (for example, a graphic processing unit (GPU)), a digital signal processor, a cryptographic processor, a microprocessor, a microcontroller, or the like; a logic chip such as an analog-to-digital converter, an application-specific integrated circuit (ASIC), or the like; and the like. However, the chip related components 1020 are not limited thereto, but may also include other types of chip related components. In addition, these components 1020 may be combined with each other.

The network related components 1030 may include protocols such as wireless fidelity (Wi-Fi) (Institute of Electrical and Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, 5G protocols and any other wireless and wired protocols designated after the above-mentioned protocols. However, the network related components 1030 are not limited thereto, but may also include any of a plurality of other wireless or wired standards or protocols. In addition, these components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), and the like. However, other components 1040 are not limited thereto, but may also include passive components used for various other purposes, and the like. In addition, these components 1040 may be combined with each other together with the chip related components 1020 and/or the network related components 1030 described above.

The electronic device 1000 may include other components that are or are not physically and/or electrically connected to the main board 1010 depending on a type thereof. These other components may include, for example, a camera 1050, an antenna 1060, a display 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage (for example, a hard disk drive) (not illustrated), a compact disk (CD) (not illustrated), a digital versatile disk (DVD) (not illustrated), and the like. However, these other components are not limited thereto, but may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop, a netbook, a television, a video game machine, a smartwatch, or the like. However, the electronic device 1000 is not limited thereto, but may also be any other electronic device processing data.

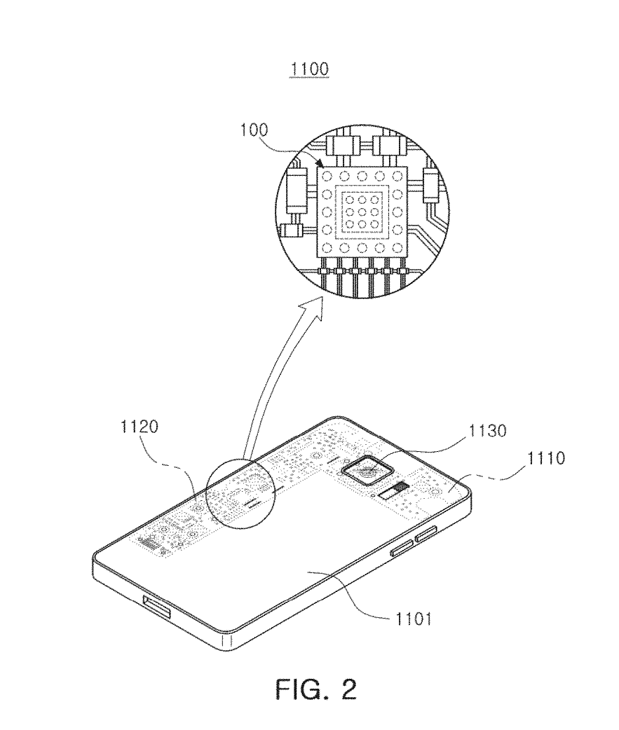

FIG. 2 is a schematic perspective view illustrating an example of an electronic device;

The semiconductor package may be used for various purposes in the various electronic devices 1000 as described above. For example, a main board 1110 may be accommodated in a body 1101 of a smart phone 1100, and various electronic components 1120 may be physically and/or electrically connected to the main board 1110. In addition, another component that may be or may not be physically and/or electrically connected to the main board 1110, such as a camera 1130, may be accommodated in the body 1101. Here, some of the electronic components 1120 may be the chip related components as described above, and the fan-out semiconductor package 100 may be, for example, an application processor among the chip related components, but is not limited thereto.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a main board of the electronic device in terms of electrical connections. In detail, a size of connection pads of the semiconductor chip and an interval between the connection pads of the semiconductor chip are very fine, but a size of component mounting pads of the main board used in the electronic device and an interval between the component mounting pads of the main board are significantly larger than those of the semiconductor chip. Therefore, it may be difficult to directly mount the semiconductor chip on the main board, and packaging technology for buffering a difference in a circuit width between the semiconductor chip and the main board is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

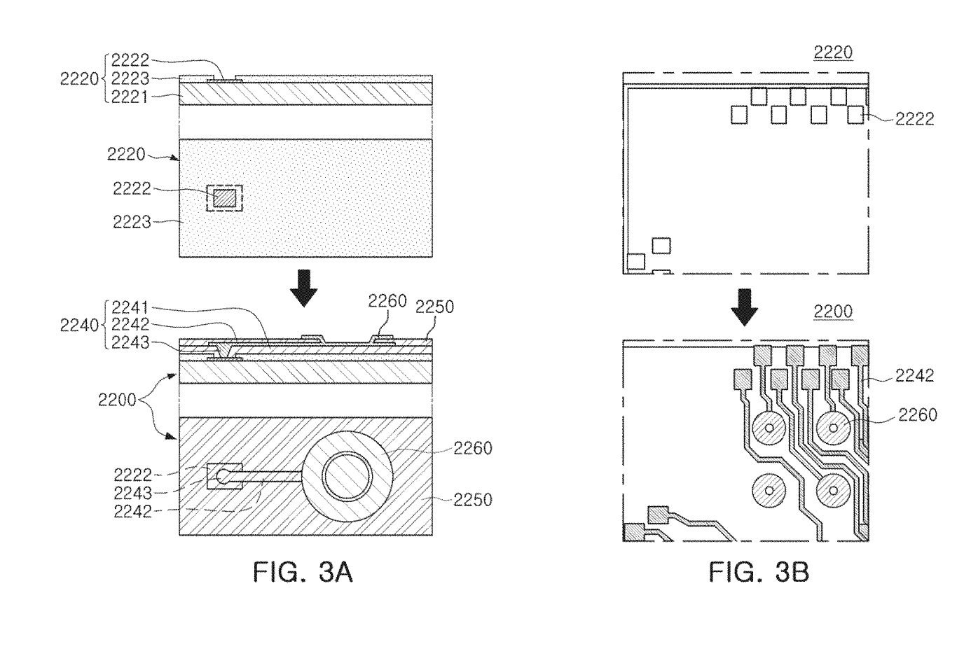

FIGS. 3A and 3B are schematic cross-sectional views illustrating states of a fan-in semiconductor package before and after being packaged.

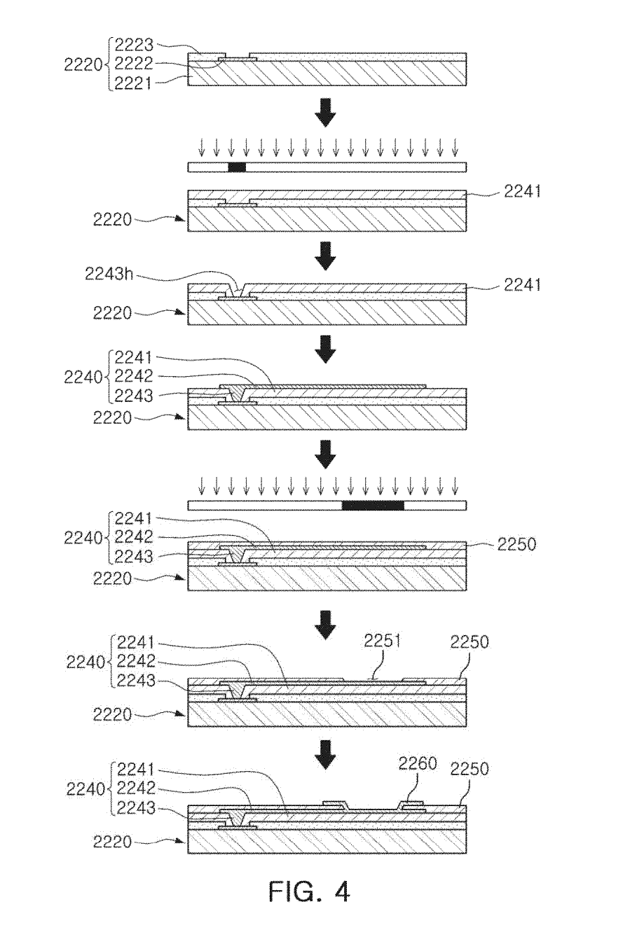

FIG. 4 is schematic cross-sectional views illustrating a packaging process of a fan-in semiconductor package.

Referring to the drawings, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 are significantly small, it is difficult to mount the integrated circuit (IC) on an intermediate level printed circuit board (PCB) as well as on the main board of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming via holes 2243h opening the connection pads 2222, and then forming redistribution layers 2242 and vias 2243. Then, a passivation layer 2250 protecting the connection member 2240 may be formed, an opening 2251 may be formed, and an under-bump metal layer 2260, or the like, may be formed. That is, a fan-in semiconductor package 2200 including, for example, the semiconductor chip 2220, the connection member 2240, the passivation layer 2250, and the under-bump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has a large spatial limitation. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the main board of the electronic device. The reason is that even in the case that a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the main board of the electronic device.

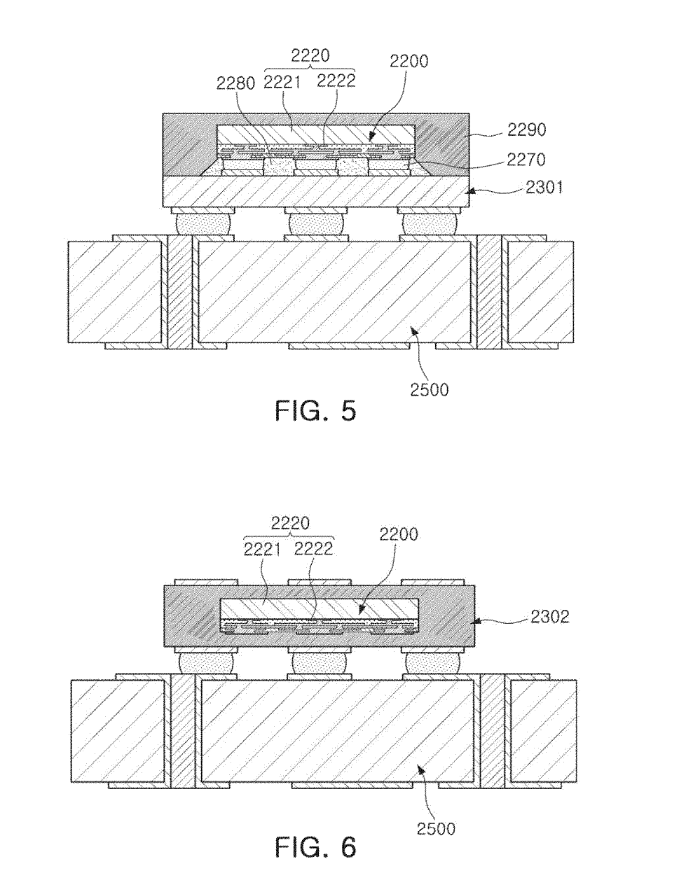

FIG. 5 is a schematic cross-sectional view illustrating a case in which a fan-in semiconductor package is mounted on an interposer substrate and is finally mounted on a main board of an electronic device.

FIG. 6 is a schematic cross-sectional view illustrating a case in which a fan-in semiconductor package is embedded in an interposer substrate and is finally mounted on a main board of an electronic device.

Referring to the drawings, in a fan-in semiconductor package 2200, connection pads 2222, that is, I/O terminals, of a semiconductor chip 2220 may be redistributed through an interposer substrate 2301, and the fan-in semiconductor package 2200 may be finally mounted on a main board 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be finally mounted on a main board 2500 of an electronic device.

As described above, it may be difficult to directly mount and use the fan-in semiconductor package on the main board of the electronic device. Therefore, the fan-in semiconductor package may be mounted on the separate interposer substrate and be then mounted on the main board of the electronic device through a packaging process or may be mounted and used on the main board of the electronic device in a state in which it is embedded in the interposer substrate.

Fan-Out Semiconductor Package

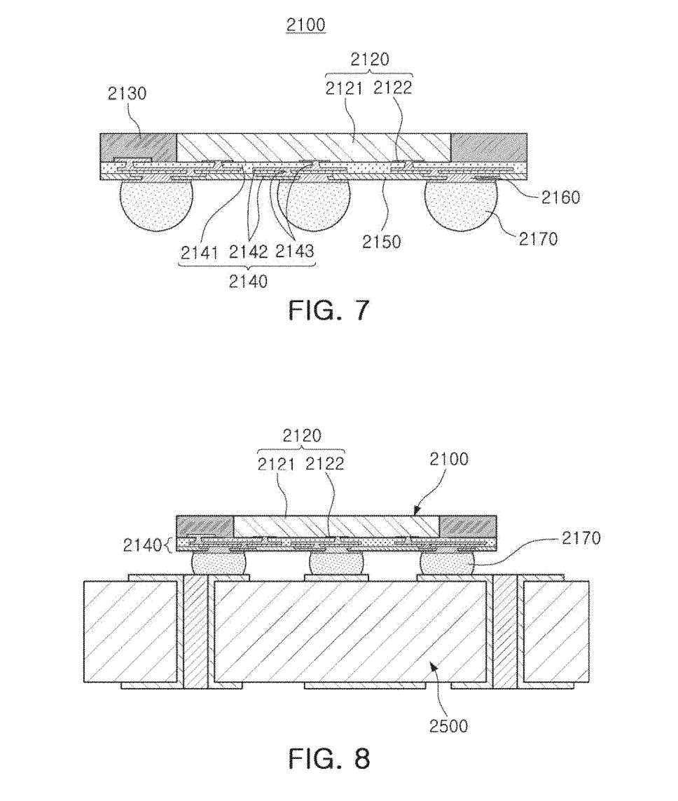

FIG. 7 is a schematic cross-sectional view illustrating a fan-out semiconductor package.

Referring to the drawing, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may be further formed on the connection member 2140, and an under-bump metal layer 2160 may be further formed in openings of the passivation layer 2150. Solder balls 2170 may be further formed on the under-bump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in the case that a size of the semiconductor chip is decreased, a standardized ball layout may be used in the fan-out semiconductor package as it is, such that the fan-out semiconductor package may be mounted on the main board of the electronic device without using a separate interposer substrate, as described below.

FIG. 8 is a schematic cross-sectional view illustrating a case in which a fan-out semiconductor package is mounted on a main board of an electronic device.

Referring to the drawing, a fan-out semiconductor package 2100 may be mounted on a main board 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the main board 2500 of the electronic device without using a separate interposer substrate, or the like.

As described above, since the fan-out semiconductor package may be mounted on the main board of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the main board of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

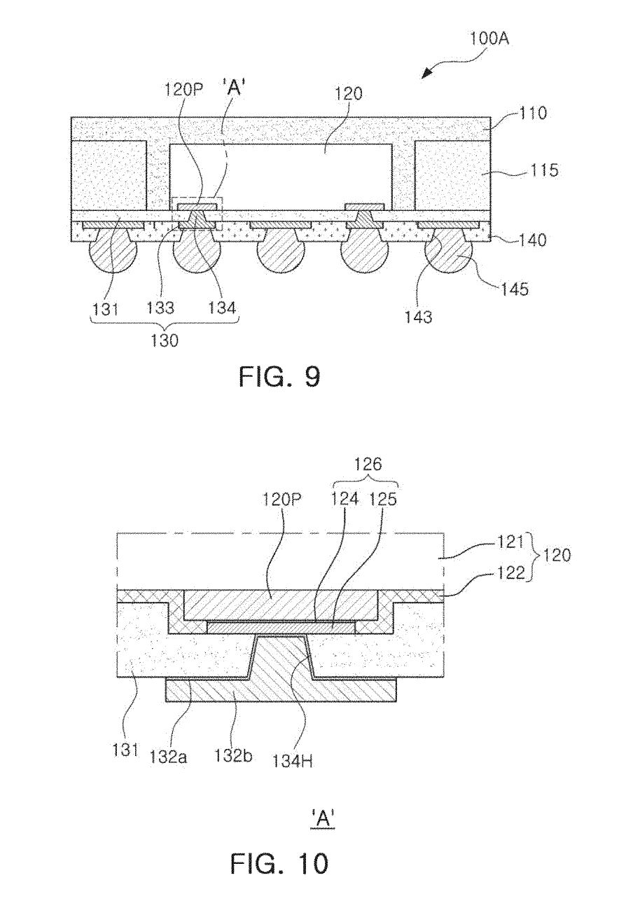

FIG. 9 is a cross-sectional view schematically illustrating an example of a fan-out semiconductor package.

FIG. 10 is a schematic enlarged view of region A of the fan-out semiconductor package of FIG. 9.

Referring to FIGS. 9 and 10, a fan-out semiconductor package 100A according to an example may include an interconnection member 115 having a through-hole, an electronic component 120 disposed in the through-hole of the interconnection member 115, an encapsulant 110 encapsulating the electronic component 120, an interconnection member 130 disposed on one side of the electronic component 120, an outer layer 140 disposed on one side of the interconnection member 130, and connection terminals 145 disposed in opening parts 143 of the outer layer 140. The electronic component 120 may include a body 121, electrode pads 120P disposed on the body 121, and a passivation layer 122 disposed on the body and covering portions of the electrode pads 120P. The interconnection member 130 may include an insulating layer 131, conductive patterns 133 disposed on the insulating layer 131, and conductive vias 134 penetrating through the insulating layer 131 and connected to the conductive patterns 133. Here, a metal layer 126 connecting the electrode pad 120P of the electronic component 120 and the conductive via 134 of the interconnection member 130 connected to the electrode pad 120P to each other may be disposed between the electrode pad 120P and the conductive via 134. The metal layer 126 may include an interlayer seed layer 124 and an interlayer conductor layer 125.

Generally, the electrode pad of the electronic component may be formed of a material such as aluminum (Al), or the like, and the via of the interconnection member connected to the electrode pad may include a seed layer formed of titanium (Ti), or the like, and a conductor layer formed of copper (Cu), or the like. Since a difference between coefficients of thermal expansion (CTEs) of aluminum (Al), titanium (Ti), and copper (Cu) is significantly large, in a case in which stress is concentrated on the via, a TC failure such as a crack or interfacial delamination may be easily generated due to weak adhesion. In addition, a natural oxide layer formed of Al₂O₃, or the like, may be generated on a surface of the electrode pad of the electronic component. The natural oxide layer may be removed through plasma pre-processing. Here, in a process of removing the natural oxide layer through the plasma pre-processing, or the like, an organic material of the insulating layer of the interconnection member and moisture may pollute the electrode pad. As a result, these pollutants may be present on an interface between the seed layer of the via formed subsequently and the electrode pad, such that close adhesion between the via and the electrode pad may be reduced.

On the other hand, in a case in which the metal layer 126 connecting the electrode pad 120P of the electronic component 120 and the conductive via 134 of the interconnection member 130 connected to the electrode pad 120P to each other is disposed between the electrode pad 120P and the conductive via 134 as in the fan-out semiconductor package 100A according to an example, the same type of material as that of the conductive via 134 may be applied to an interface of the conductive via 134 on which the stress is concentrated, such that a difference between CTEs may be reduced. As a result, the adhesion between the electrode pad and the conductive via may be improved, such that the TC failure such as interfacial delamination may not be easily generated even in a case in which the stress is concentrated on the conductive via. In addition, since the seed layer 132a of the conductive via 134 is not formed on the surface of the electrode pad 120P and the surface of the electrode pad 120P may be cleaned before the conductive via 134 is formed, the pollution of the interface due to the plasma pre-processing, or the like, may be reduced.

Hereinafter, respective components of the fan-out semiconductor package 100A according to an example will be described in more detail.

The electronic component 120 may be various active components (for example, a diode, a vacuum tube, a transistor, and the like) or passive components (for example, an inductor, a condenser, a resistor, and the like). Alternatively, the electronic component 120 may be an integrated circuit (IC) indicating a chip in which hundreds to millions or more of elements are integrated. The integrated circuit may be an application processor chip such as a central processor (for example, a CPU), a graphic processor (for example, a GPU), a digital signal processor, a cryptographic processor, a microprocessor, a microcontroller, or the like, but is not limited thereto.

In the case in which the electronic component 120 is the integrated circuit, the electronic component may have the body 121, the passivation layer 122, and the electrode pads 120P. The body 121 may be formed on the basis of, for example, an active wafer. In this case, silicon (Si), germanium (Ge), gallium arsenide (GaAs), or the like, may be used as a basic material of the body 121. The passivation layer 122 may serve to protect the body 121 from the outside, and may be formed of, for example, an oxide layer, a nitride layer, or the like, or be formed of a double layer of an oxide layer and a nitride layer. The oxide layer may be formed of SiO₂, or the like, and the nitride layer may be formed of Si₃N₄, or the like. However, materials of the oxide layer and the nitride layer are not limited thereto. A conductive material such as aluminum (Al), an aluminum alloy, or the like, may be used as a material of the electrode pad 120P. The passivation layer 122 and the electrode pad 120P may be disposed on a surface of the electronic component 120. Here, the passivation layer 122 may cover a portion of the electrode pad 120P. The electrode pad 120P may be redistributed by the interconnection member 130. The electrode pad 120P may have an embedded form or a protruding form. A layer on which the electrode pads 120P are formed may become an active layer.

A thickness of the electronic component 120 in a cross section thereof is not particularly limited, but may be changed depending on a type of electronic component 120. For example, in a case in which the electronic component is the integrated circuit, a thickness of the electronic component may be about 100 μm to 480 μm, but is not limited thereto. The thickness of the electronic component 120 in the cross-section thereof may be the same as or be thinner than that of a interconnection member 115 in a cross-section thereof to be described below. In this case, the electronic component may be more easily protected.

The metal layer 126, which is to improve the adhesion of the interface between the electrode pad 120P and the conductive via 134, may include the interlayer seed layer 124 disposed on the electrode pad 120P and the interlayer conductor layer 125 disposed on the interlayer seed layer 124. The interlayer seed layer 124 may contain one or more of titanium (Ti), titanium-tungsten (Ti—W), molybdenum (Mo), chrome (Cr), nickel (Ni), and nickel-chrome (Ni—Cr). The interlayer seed layer 124 may generally have a thickness of 1 μm or less, but is not limited thereto. The interlayer conductor layer 125 may contain a conductive material, for example, copper (Cu), aluminum (Al), silver (Ag), tin (Sn), gold (Au), nickel (Ni), lead (Pd), or alloys thereof, and may generally contain copper (Cu). The interlayer conductor layer 125 may generally have a thickness of 10 μm or less, but is not limited thereto. The metal layer 126 may contact the passivation layer 122, and only a portion of a surface of the metal layer 126 may be exposed by a via hole 134H. However, the metal layer 126 is not limited thereto.

The interconnection member 130 may be provided to redistribute the electrode pads 120P of the electronic component 120. Tens to hundreds of electrode pads 120P having various functions may be redistributed through the interconnection member 130, and may be physically and/or electrically connected to the outside through the connection terminals 145 depending on functions thereof. The interconnection member 130 may include the insulating layer 131, the conductive patterns 133 disposed on the insulating layer 131, and the conductive vias 134 penetrating through the insulating layer 131 and connected to the conductive patterns 133. The interconnection member 130 is not necessarily formed of a single layer, but may be formed of a plurality of layers, unlike in the illustrations of FIGS. 3 and 4. The conductive pattern 133 and the conductive via 134 may include the seed layer 132a and the conductor layer 132b.

For example, an insulating material may be used as a material of the insulating layer 131. Here, the insulating material may be a thermosetting resin such as an epoxy resin, a thermoplastic resin such as a polyimide resin, a resin having a reinforcing material such as a glass fiber or an inorganic filler impregnated in the thermosetting resin and the thermoplastic resin, for example, prepreg, Ajinomoto Build up Film (ABF), FR-4, Bismaleimide Triazine (BT), or the like. In a case in which a photosensitive insulating material such as a photo imagable dielectric (PID) resin is used as a material of the insulating layer 131, the insulating layer 131 may be formed at a reduced thickness, and a fine pitch may be easily implemented.

The conductive pattern 133 may serve as a redistribution wiring, or the like, and a conductive material such as copper (Cu), aluminum (Al), silver (Ag), tin (Sn), gold (Au), nickel (Ni), lead (Pd), or alloys thereof, or the like, may be used as a material of the conductive pattern 133. The conductive pattern 133 may perform various functions depending on a design of the corresponding layer. For example, the conductive pattern 133 may serve as a ground (GND) pattern, a power (PWR) pattern, a signal (S) pattern, and the like. Here, the signal (S) pattern may include various signals except for the ground (GND) pattern, the power (PWR) pattern, and the like, for example, data signals, and the like. In addition, the conductive pattern 133 may also serve as a pad such as a via pad, a connection terminal pad, or the like.

The conductive via 134 may electrically connect the conductive pattern 133, the electrode pad 120P, and the like, formed on different layers to each other, thereby forming an electrical path within the fan-out semiconductor package 100A. A conductive material such as copper (Cu), aluminum (Al), silver (Ag), tin (Sn), gold (Au), nickel (Ni), lead (Pd), or alloys thereof, or the like, may be used as a material of the conductive via 134. The conductive via 134 may be completely filled with a conductive material. Alternatively, a conductive material may be formed along a wall of the conductive via 134. In addition, the conductive via 134 may have all of the shapes known in the related art, such as a tapered shape in which a diameter of the via is reduced toward a lower surface, a reverse tapered shape in which a diameter of the via is increased toward a lower surface, a cylindrical shape, and the like.

The conductive pattern 133 and the conductive via 134 may include the seed layer 132a and the conductor layer 132b. The seed layer 132a may be disposed on the surface of the metal layer 126 exposed by the via hole 134H and a wall of the via hole 134H. In addition, the seed layer 132a may be disposed on a surface of the insulating layer 131. The conductor layer 132b may be disposed on the seed layer 132a. The seed layer 132a may include a first seed layer containing one or more of titanium (Ti), titanium-tungsten (Ti—W), molybdenum (Mo), chrome (Cr), nickel (Ni), and nickel-chrome (Ni—Cr) and a second seed layer disposed on the first seed layer and containing the same material as that of the conductor layer 132b, for example, copper (Cu). The first seed layer may serve as an adhesive, and the second seed layer may serve as a basic plated layer. The conductor layer 132b may contain a conductive material, for example, copper (Cu), aluminum (Al), silver (Ag), tin (Sn), gold (Au), nickel (Ni), lead (Pd), or alloys thereof, and may generally contain copper (Cu).

The outer layer 140 may be an additional component for protecting the interconnection member 130 from external physical or chemical damage, or the like. A material of the outer layer 140 is not particularly limited. For example, a solder resist may be used as a material of the outer layer 140. That is, the outer layer 140 may be a solder resist layer. In addition, the same material as that of the insulating layer 131 of the interconnection member 130, for example, the same PID resin may also be used as a material of the outer layer 140. The outer layer 140 is generally a single layer, but may also be formed of multiple layers, if necessary. The outer layer 140 may have the opening parts 143 opening at least portions of the conductive patterns 133. A shape of the opening part 143 may be a circular shape or an oval shape, but is not limited thereto.

The connection terminals 145 may be to physically and/or electrically connect the fan-out semiconductor package 100A externally. For example, the fan-out semiconductor package 100A may be mounted on the main board of the electronic device through the connection terminals 145. The connection terminals 145 may be disposed in the opening parts 143, and be connected to the conductive patterns 133 exposed through the opening parts 143. Therefore, the connection terminals 145 may also be electrically connected to the electronic component 120. The connection terminal 145 may be formed of a conductive material, for example, copper (Cu), aluminum (Al), silver (Ag), tin (Sn), gold (Au), nickel (Ni), lead (Pd), solder, or the like, but is not particularly limited thereto. The connection terminal 145 may be a land, a ball, a pin, or the like. The connection terminal 145 may be formed of multiple layers or a single layer. In a case in which the connection terminal 145 is formed of the multiple layers, the connection terminal 145 may contain a copper pillar and a solder, and in a case in which the connection terminal 145 is formed of the single layer, the connection terminal 145 may contain a tin-silver solder or copper. However, this is only an example, and the connection terminal 145 is not limited thereto.

At least one of the connection terminals 145 may be disposed in a fan-out region. The fan-out region is a region except for a region in which the electronic component is disposed. That is, the fan-out semiconductor package 100A according to an example may be a fan-out package. The fan-out package may have greater reliability than that of a fan-in package, may implement a plurality of I/O terminals, and may easily perform 3D interconnection. In addition, since the fan-out package may be mounted on the electronic device without using a separate substrate as compared to a ball grid array (BGA) package, a land grid array (LGA) package, or the like, the fan-out package may be manufactured at a reduced thickness, and may have excellent price competitiveness. The number, an interval, a disposition form, and the like, of connection terminals 145 are not particularly limited, but may be sufficiently modified depending on design particulars by those skilled in the art. For example, the number of connection terminals 145 may be several ten to several thousand depending on the number of electrode pads 120P of the electronic component 120. However, the number of connection terminals 145 is not limited thereto, but may also be several ten to several thousand or more or several ten to several thousand or less.

The encapsulant 110 may be an additional component for protecting the electronic component 120. A detailed material of the encapsulant 110 is not particularly limited. For example, an insulating material may be used as a material of the encapsulant 110. Here, the insulating material may be a thermosetting resin such as an epoxy resin, a thermoplastic resin such as a polyimide resin, a resin having a reinforcing material such as a glass fiber or an inorganic filler impregnated in the thermosetting resin and the thermoplastic resin, for example, prepreg, ABF, FR-4, BT, a PID resin, or the like. In addition, the known molding material such as an epoxy molding compound (EMC), or the like, may also be used. The encapsulant 110 may contain conductive particles in order to block electromagnetic waves, if necessary. For example, the conductive particle may be any material that may block the electromagnetic wave, for example, copper (Cu), aluminum (Al), silver (Ag), tin (Sn), gold (Au), nickel (Ni), lead (Pd), solder, or the like, but is not particularly limited thereto.

The interconnection member 115 may be an additional component for supporting the fan-out semiconductor package 100A, and rigidity of the fan-out semiconductor package 100A may be maintained and uniformity of a thickness of the fan-out semiconductor package 100A may be secured by the interconnection member. The interconnection member 115 may have the upper surface and the lower surface opposing the upper surface. Here, the through-hole may penetrate between the upper surface and the lower surface. The electronic component 120 may be disposed in the through-hole so as to be spaced apart from the interconnection member 115. As a result, the surrounding of side surfaces of the electronic component 120 may be enclosed by the interconnection member 115. A material of the interconnection member 115 is not particularly limited as long as the interconnection member may support the fan-out semiconductor package. For example, an insulating material may be used as a material of the interconnection member 115. Here, the insulating material may be a thermosetting resin such as an epoxy resin, a thermoplastic resin such as a polyimide resin, a resin having a reinforcing material such as a glass fiber or an inorganic filler impregnated in the thermosetting resin and the thermoplastic resin, for example, prepreg, ABF, FR-4, BT, or the like. Alternatively, a metal having excellent rigidity and thermal conductivity may be used as a material of the interconnection member 115. Here, the metal may be a Fe—Ni based alloy. In this case, a Cu plating may also be formed on a surface of the Fe—Ni based alloy in order to secure adhesion between the Fe—Ni based alloy and a molding material, an interlayer insulating material, or the like. In addition to the materials as described above, glass, ceramic, plastic, or the like, may also be used as a material of the interconnection member 115. A thickness of the interconnection member 115 in a cross section thereof is not particularly limited, but may be designed depending on a thickness of the electronic component 120 in a cross section thereof. For example, a thickness of the interconnection member 115 in the cross section thereof may be about 100 μm to 500 μm.

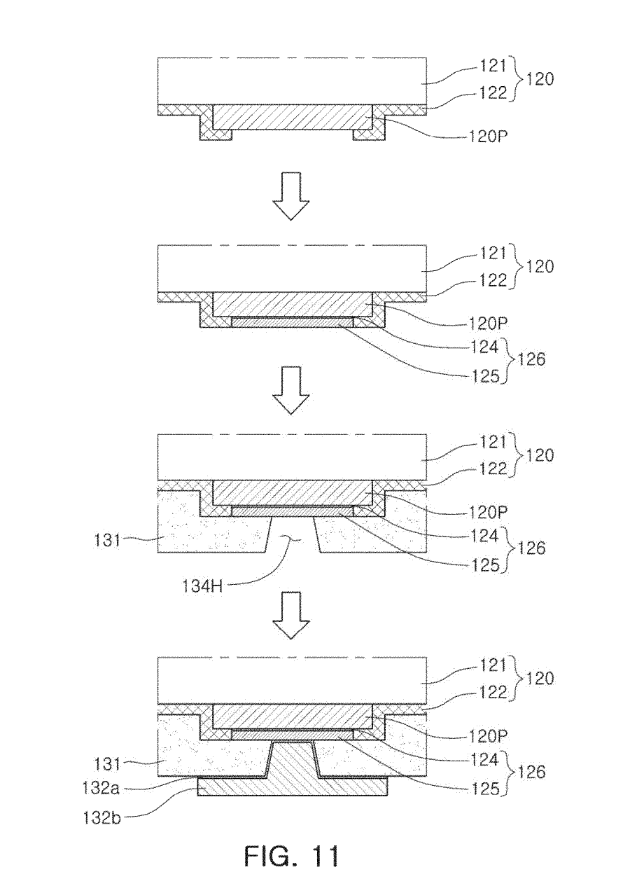

FIG. 11 is a view schematically illustrating an example of processes of manufacturing region A of the fan-out semiconductor package of FIG. 10.

Referring to FIG. 11, the electronic component 120 including the body 121, the passivation layer 122, and the electrode pads 120P may be first prepared. The passivation layer 122 may be an additional component. The electronic component 120 may be a general semiconductor chip, and since a detailed content of the electronic component 120 is the same as the content described above, descriptions thereof will be omitted. Although not illustrated in detail in FIG. 11, the natural oxide layer formed of Al₂O₃, or the like, other organic materials, or the like, may be generated on the surface of the electrode pad 120P. The natural oxide layer or other organic materials may be removed through the plasma pre-processing, or the like, before the metal layer 126 is formed. In this case, the pollution of the electrode pad 120P due to the organic material of the insulating layer 131 and the moisture may be prevented. In addition, although not illustrated in detail in FIG. 11, after the electronic component 120 is prepared and before the metal layer 126 is formed, the electronic component 120 may be disposed in the through-hole of the interconnection member 115, and may be encapsulated with the encapsulant 110.

Referring to FIG. 11, next, the metal layer 126 may be formed on the electrode pad 120P. The metal layer 126 may include the interlayer seed layer 124 and the interlayer conductor layer 125. The interlayer seed layer 124 may be first formed, and the interlayer conductor layer 125 may be formed on the interlayer seed layer 124. The interlayer seed layer 124 may be formed using chemical vapor deposition (CVD), physical vapor deposition (PVD), sputtering, or the like, but is not limited thereto. The interlayer conductor layer 125 may be formed using electroplating, or the like, but is not limited thereto. Since contents for materials, and the like, of the interlayer seed layer 124 and the interlayer conductor layer 125 are the same as the contents described above, descriptions thereof will be omitted.

Referring to FIG. 11, next, the insulating layer 131 may be formed on one side of the electronic component 120. Then, the via hole 134H penetrating through the insulating layer 131 and opening a portion of the metal layer 126 may be formed. The insulating layer 131 may be formed by the known method, for example, a method of laminating a precursor of the insulating layer 131 and then hardening the precursor, a method of applying a material for forming the insulating layer 131 and then hardening the material, or the like, but is not limited thereto. As the method of laminating the precursor, for example, a method of performing a hot press process of pressing the precursor for a predetermined time at a high temperature, decompressing the precursor, and then cooling the precursor to a room temperature, cooling the precursor in a cold press process, and then separating a work tool, or the like, may be used. As the method of applying the material, for example, a screen printing method of applying ink by squeeze, a spray printing method of applying ink in a mist form, or the like, may be used. The hardening process, which is a post-process, may be a process of drying the material so as not to be completely hardened in order to use a photolithography method, or the like. The via hole 134H may be formed by the known method, for example, a mechanical drilling and/or a laser drilling, or a photolithography method in a case in which the insulating layer 131 contains the photosensitive material.

Referring to FIG. 11, next, the seed layer 132a may be formed on the surface of the metal layer 126 exposed by the via hole 134H, the wall of the via hole 134H, and the surface of the insulating layer 131, and the conductor layer 132b may be formed on the seed layer 132a. As a result, the conductive pattern 133 and the conductive via 134 may be formed. Thus, the interconnection member 130 may be formed. The seed layer 132a may be formed using CVD, PVD, sputtering, or the like, but is not limited thereto. The conductor layer 132b may be formed using electroplating, or the like, but is not limited thereto. Since contents for materials, and the like, of the seed layer 132a and the conductor layer 132b are the same as the contents described above, descriptions thereof will be omitted. Although not illustrated in detail in FIG. 11, after the interconnection member 130 is formed, the outer layer 140 may be formed by the known lamination method, application method, or the like, the openings 143 may be formed in the outer layer 140 using a mechanical drill and/or a laser drill, a photolithography method, or the like, and the connection terminals 145 may be formed in the opening parts 143 by the known method.

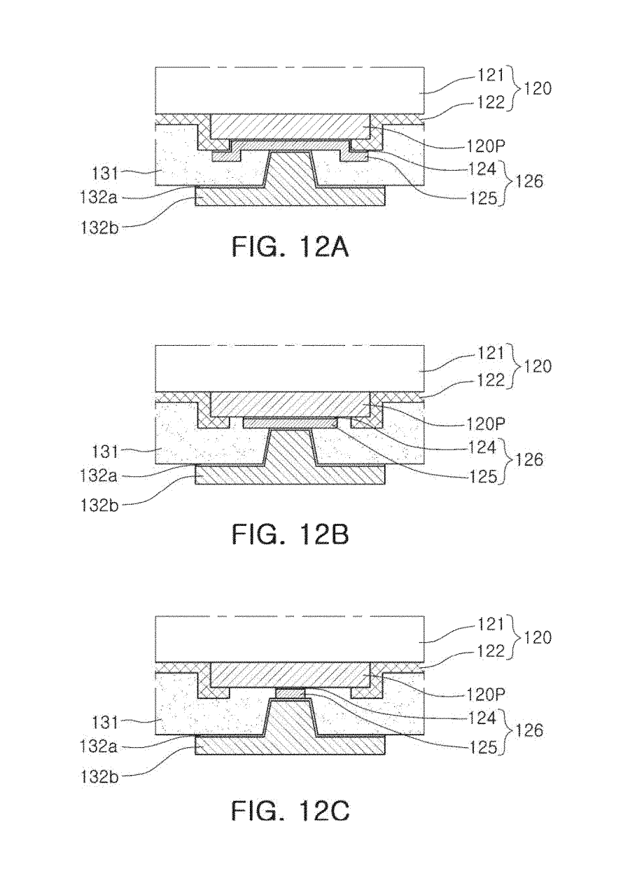

FIGS. 12A through 12C are views schematically illustrating modified examples of region A of the fan-out semiconductor package of FIG. 10.

Referring to FIGS. 12A through 12C, the metal layer 126 may also be partially disposed on the passivation layer 122, and only a portion of a surface of the metal layer 126 may be exposed by the via hole 134H, as illustrated in FIG. 12A. Alternatively, the metal layer 126 may be disposed to be spaced apart from the passivation layer 122, and only a portion of a surface of the metal layer 126 may be exposed by the via hole 134H, as illustrated in FIG. 12B. Alternatively, the metal layer 126 may be disposed to be spaced apart from the passivation layer 122, and an entire surface of the metal layer 126 may be exposed by the via hole 134H, as illustrated in FIG. 12C. However, the disposition forms described above are only examples. That is, the metal layer 126 may be disposed in other forms.

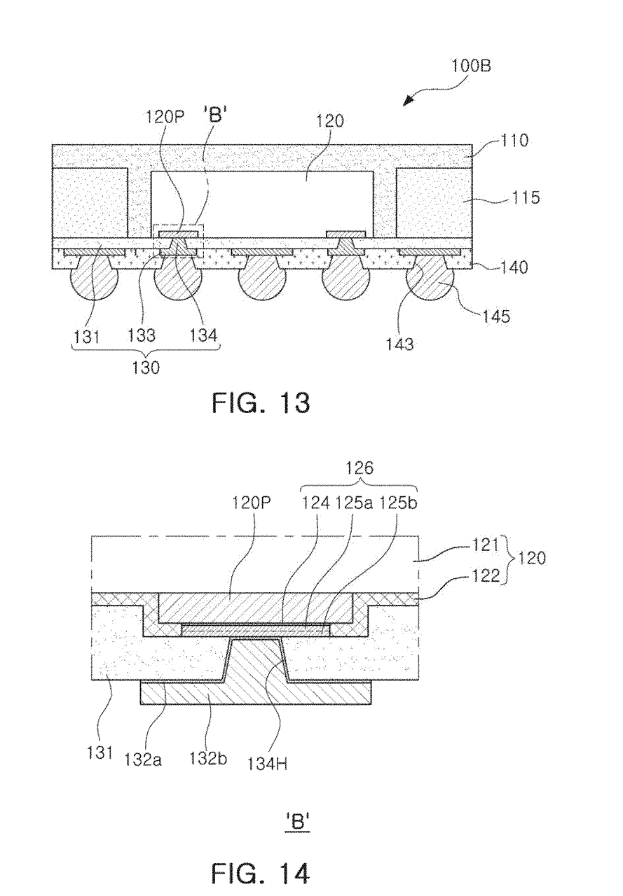

FIG. 13 is a cross-sectional view schematically illustrating another example of a fan-out semiconductor package.

FIG. 14 is a schematic enlarged view of region B of the fan-out semiconductor package of FIG. 13.

Referring to FIGS. 13 and 14, in a fan-out semiconductor package 100B according to another example, interlayer conductor layers 125a and 125b of the metal layer 126 may be formed of a plurality of layers. That is, the interlayer conductor layers 125a and 125b may include a first interlayer conductor layer 125a disposed on the interlayer seed layer 124 and a second interlayer conductor layer 125b disposed on the first interlayer conductor layer 125a and partially exposed by the via hole 134H. The first and second interlayer conductor layers 125a and 125b may contain a conductive material, for example, copper (Cu), aluminum (Al), silver (Ag), tin (Sn), gold (Au), nickel (Ni), lead (Pd), or alloys thereof, and may generally contain copper (Cu). The first and second interlayer conductor layers 125a and 125b may have a thickness of 10 μm or less, respectively, and a boundary between the first and second interlayer conductor layers 125a and 125b may be distinguished depending on a method of forming the first and second interlayer conductor layers 125a and 125b. For example, the first interlayer conductor layer 125a may be formed by sputtering, and the second interlayer conductor layer 125b may be formed by electroplating. In this case, the boundary between the first and second interlayer conductor layers 125a and 125b may be distinguished as described below. Since other components are the same as the components described above, descriptions thereof will be omitted.

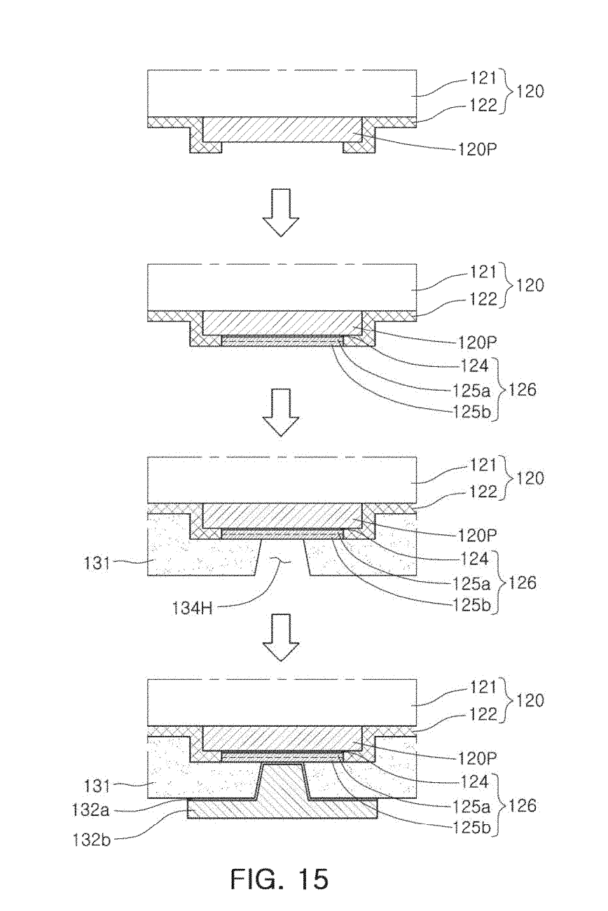

FIG. 15 is a view schematically illustrating an example of processes of manufacturing region B of the fan-out semiconductor package of FIG. 14.

Referring to FIG. 15, in the processes of manufacturing the fan-out semiconductor package 100B according to another example, the electronic component 120 may be prepared, and the metal layer 126 may be formed on the electrode pad 120P. Here, the interlayer conductor layers 125a and 125b of the metal layer 126 may be formed as the plurality of layers. The first interlayer conductor layer 125a may be formed using CVD, PVD, sputtering, or the like, but is not limited thereto. The second interlayer conductor layer 125b may be formed using electroplating, or the like, but is not limited thereto. Since other contents are the same as the contents described above, descriptions thereof will be omitted.

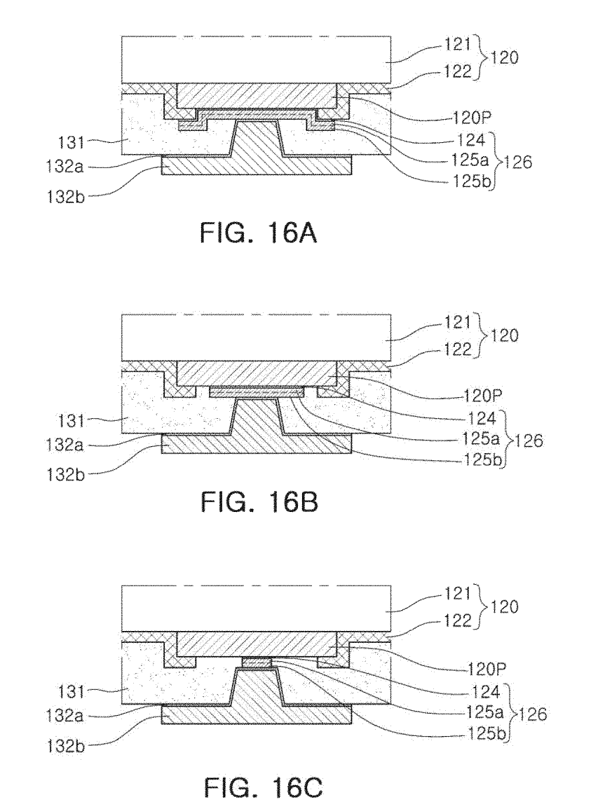

FIGS. 16A through 16C are views schematically illustrating modified examples of region B of the fan-out semiconductor package of FIG. 14.

Referring to FIGS. 16A through 16C, also in a case in which the interlayer conductor layers 125a and 125b of the metal layer 126 are formed of the plurality of layers, the metal layer 126 may also be partially disposed on the passivation layer 122, and only a portion of a surface of the metal layer 126 may be exposed by the via hole 134H, as illustrated in FIG. 16A. Alternatively, the metal layer 126 may be disposed to be spaced apart from the passivation layer 122, and only a portion of a surface of the metal layer 126 may be exposed by the via hole 134H, as illustrated in FIG. 16B. Alternatively, the metal layer 126 may be disposed to be spaced apart from the passivation layer 122, and an entire surface of the metal layer 126 may be exposed by the via hole 134H, as illustrated in FIG. 16C. However, the disposition forms described above are only examples. That is, the metal layer 126 may be disposed in other forms.

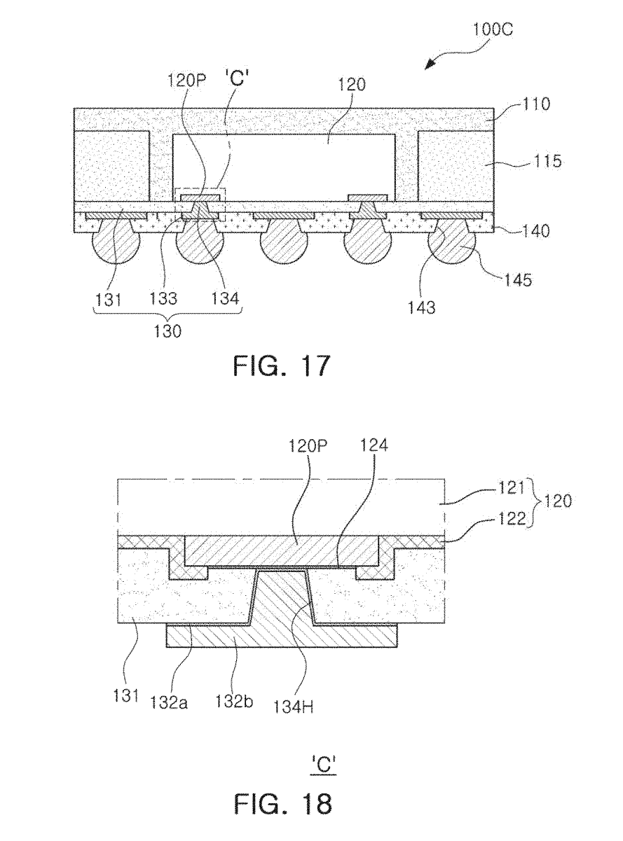

FIG. 17 is a cross-sectional view schematically illustrating another example of a fan-out semiconductor package.

FIG. 18 is a schematic enlarged view of region C of the fan-out semiconductor package of FIG. 17.

Referring to FIGS. 17 and 18, in a fan-out semiconductor package 100C according to another example, the metal layer 126 may only include the interlayer seed layer 124. The interlayer seed layer 124 may be a single seed layer containing one or more of titanium (Ti), titanium-tungsten (Ti—W), molybdenum (Mo), chrome (Cr), nickel (Ni), and nickel-chrome (Ni—Cr), but is not limited thereto. Since other components are the same as the components described above, descriptions thereof will be omitted.

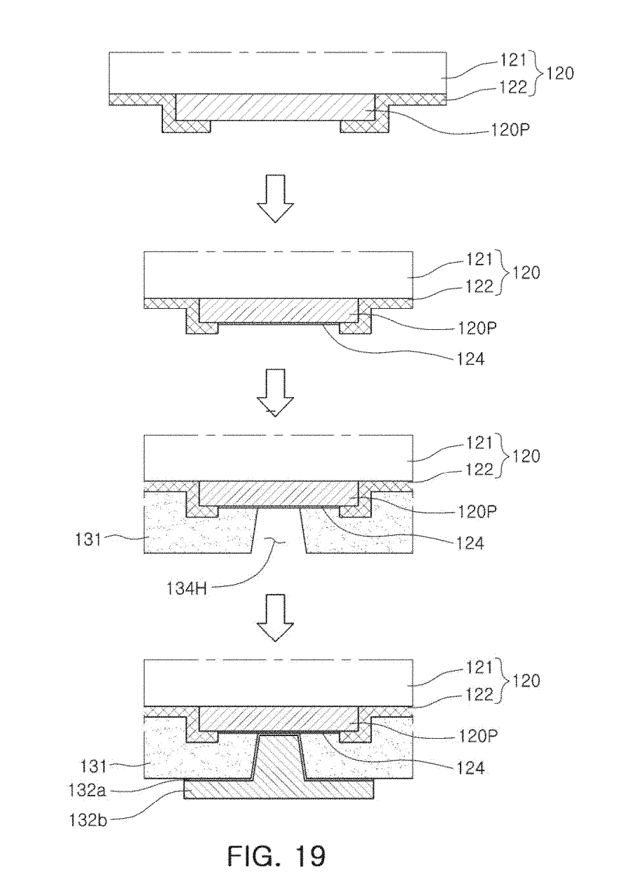

FIG. 19 is a view schematically illustrating an example of processes of manufacturing region C of the fan-out semiconductor package of FIG. 18.

Referring to FIG. 19, in the processes of manufacturing the fan-out semiconductor package 100C according to another example, the electronic component 120 may be prepared, and the metal layer 126 may be formed on the electrode pad 120P. Here, the metal layer 126 may include only the interlayer seed layer 124. The interlayer seed layer 124 may be formed using chemical vapor deposition (CVD), physical vapor deposition (PVD), sputtering, or the like, but is not limited thereto. Since other contents are the same as the contents described above, descriptions thereof will be omitted.

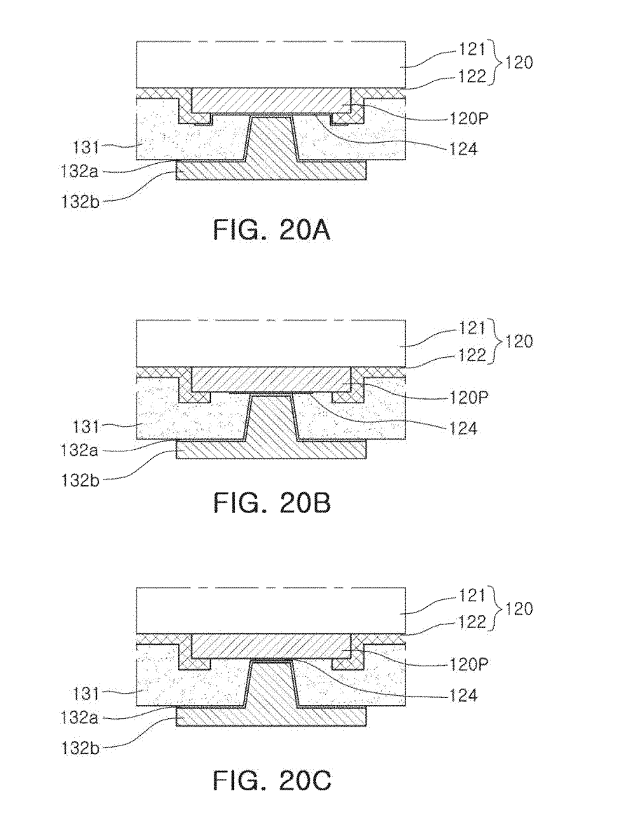

FIGS. 20A through 20C are views schematically illustrating modified examples of region C of the fan-out semiconductor package of FIG. 18.

Referring to FIGS. 20A through 20C, also in a case in which the metal layer 126 only includes the interlayer seed layer 124, the metal layer 126 may also be partially disposed on the passivation layer 122, and only a portion of a surface of the metal layer 126 may be exposed by the via hole 134H, as illustrated in FIG. 20A. Alternatively, the metal layer 126 may be disposed to be spaced apart from the passivation layer 122, and only a portion of a surface of the metal layer 126 may be exposed by the via hole 134H, as illustrated in FIG. 20B. Alternatively, the metal layer 126 may be disposed to be spaced apart from the passivation layer 122, and an entire surface of the metal layer 126 may be exposed by the via hole 134H, as illustrated in FIG. 20C. However, the disposition forms described above are only examples. That is, the metal layer 126 may be disposed in other forms.

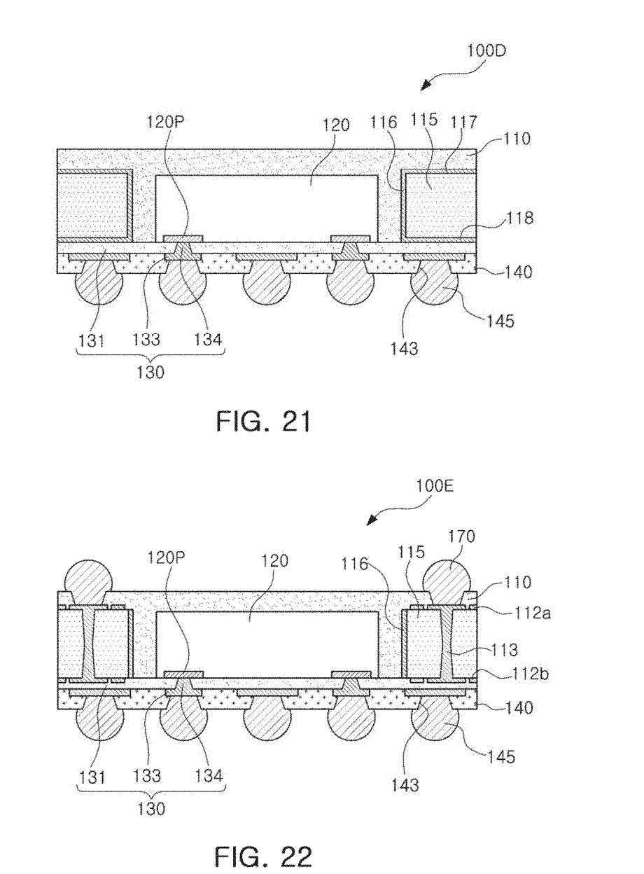

FIG. 21 is a cross-sectional view schematically illustrating another example of a fan-out semiconductor package.

Referring to FIG. 21, a fan-out semiconductor package 100D according to another example may be a panel level package (PLP) type. That is, the fan-out semiconductor package 100D according to anther example may further include a interconnection member 115 disposed on the interconnection member 130 and having a through-hole. Here, the electronic component 120 may be disposed in the through-hole of the interconnection member 115. Metal layers 116, 117, and 118 may be disposed on an inner surface of the through-hole, an upper surface of the interconnection member 115, and/or a lower surface of the interconnection member 115, if necessary. The other components are the same as the components as described above.

The metal layers 116, 117, and 118 disposed on the inner surface of the through-hole, the upper surface of the interconnection member 115, and/or lower surface of the interconnection member 115, if necessary, may be to improve heat radiation characteristics and/or block electromagnetic waves. A material of the metal layers 116, 117, and 118 is not particularly limited as long as it is a metal having high thermal conductivity, such as copper (Cu), aluminum (Al), silver (Ag), tin (Sn), gold (Au), nickel (Ni), lead (Pd), or alloys thereof, or the like. Heat emitted from the electronic component 120 may be dispersed to an upper side or a lower side of the interconnection member 115 through the metal layers 116, 117, and 118 by conduction, radiation, or convection.

FIG. 22 is a cross-sectional view schematically illustrating another example of a fan-out semiconductor package.

Referring to FIG. 22, a fan-out semiconductor package 100E according to another example may be a package-on-package (PoP) type while being a panel level package (PLP) type. That is, the fan-out semiconductor package 100A according to another example may further include through-wirings 113 penetrating through the interconnection member 115. Here, various patterns 112a and 112b may be disposed on an upper surface and a lower surface of the interconnection member 115, and a metal layer 116 may be disposed on an inner surface of the through-hole, if necessary. In addition, the fan-out semiconductor package 100A may further include connection terminals 170 connected to the through-wirings 113. The other components are the same as the components as described above.

The through-wirings 113 may only penetrate through the interconnection member 115, and the number, an interval, a disposition form, and the like, of through-wirings 113 are not particularly limited, but may be sufficiently modified depending on design particulars by those skilled in the art. The connection terminals 170 may be disposed in upper opening parts (not denoted by a reference numeral) formed in an upper surface of the encapsulant 110, and the number, an interval, a disposition form, and the like, of connection terminals 170 are not particularly limited, but may be sufficiently modified depending on design particulars by those skilled in the art. The various patterns 112a and 112b disposed on the upper surface and the lower surface of the interconnection member 115 may be wiring and/or pad patterns. Since the wirings may also be formed on the upper surface and the lower surface of the interconnection member 115, as described above, a wider routing region may be provided to the fan-out semiconductor package 100E. As a result, a degree of freedom of a design of the interconnection member 130 may be further improved. The metal layer 116 disposed on the inner surface of the through-hole of the interconnection member 115, if necessary, may be to improve heat radiation characteristics and/or block electromagnetic waves. In a case in which the metal layer 116 is only disposed on the inner surface of the through-hole as described above, a heat radiation effect and electromagnetic waves blocking effect may be sufficiently accomplished.

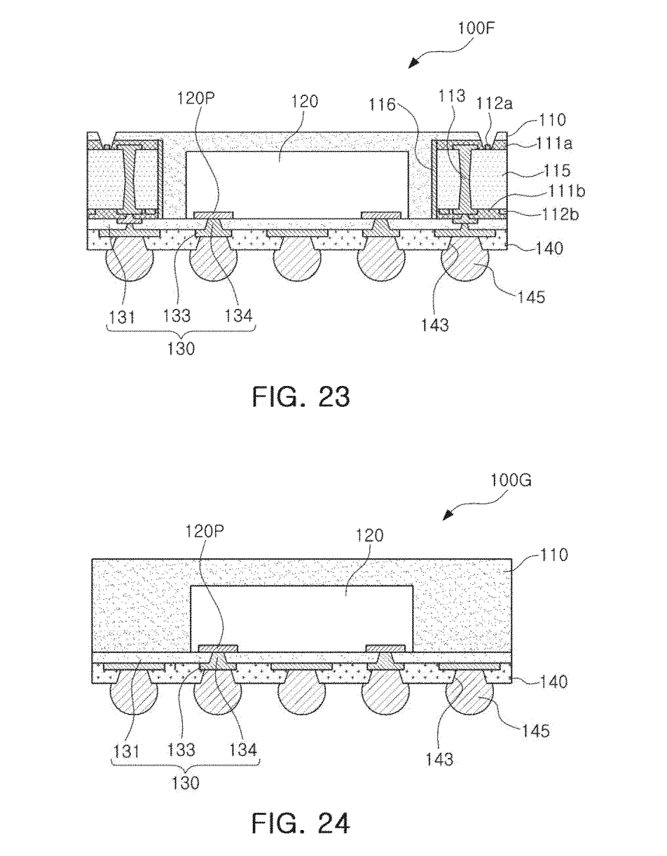

FIG. 23 is a cross-sectional view schematically illustrating another example of a fan-out semiconductor package.

Referring to FIG. 23, a fan-out semiconductor package 100F according to another example may be another package-on-package (PoP) type while being a panel level package (PLP) type. That is, insulating layers 111a and 112b having through-holes integrated with a through-hole of a interconnection member 115 may be further disposed on an upper surface and/or a lower surface of the interconnection member 115. An insulating layer 111a may have upper opening parts (not denoted by a reference numeral) formed therein so as to penetrate up to the encapsulant 110, and some of the patterns 112a may be exposed to the outside through the upper opening parts (not denoted by a reference numeral). The exposed patterns 112a may serve to pads of wire bonding of another electronic component and another electronic component package disposed on the fan-out semiconductor package 100F. The other components are the same as the components as described above.

The insulating layers 111a and 111b may be used to separate more wiring patterns before the electronic component 120 is disposed. As the numbers of insulating layers 111a and 111b are increased, more wiring patterns may be formed on the corresponding layers, such that the number of layers in the interconnection member 130 including 131, 133, and 134 may be decreased. As a result, the probability that the electronic component 120 will not be used due to a defect occurring in a process of forming the interconnection member 130 including 131, 133, and 134 after the electronic component 120 is disposed may be decreased. That is, a problem that a yield is decreased due to a process defect after the electronic component 120 is disposed may be prevented. Through-holes penetrating through the insulating layers 111a and 111b may also be formed in the insulating layers 111a and 111b, and may be integrated with the through-hole penetrating through the interconnection member 115. In this case, the electronic component 120 may be disposed in the integrated through-hole. Various patterns and vias (not denoted by a reference numeral) may also be formed on the insulating layers 111a and 111b.

An insulating material may be used as materials of the insulating layers 111a and 111b. Here, the insulating material may be a thermosetting resin such as an epoxy resin, a thermoplastic resin such as a polyimide resin, a resin having a reinforcing material such as a glass fiber or an inorganic filler impregnated in the thermosetting resin and the thermoplastic resin, for example, prepreg, ABF, FR-4, BT, or the like. In a case in which a photosensitive insulating material such as a photosensitive insulating resin is used as materials of the insulating layers 111a and 111b, the insulating layers 111a and 111b may be formed at a thinner thickness, and a fine pitch may be easily implemented. The respective insulating layers 111a and 111b may contain the same insulating material or different insulating materials. In addition, the insulating layers 111a and 111b may have approximately the same thickness or different thicknesses. In a case in which materials of the inner insulating layers 111a and 112b are the same as each other, thicknesses of the inner insulating layers 111a and 112b are approximately the same as each other, and the numbers of inner insulating layers 111a and 112b are the same as each other, the inner insulating layers 111a and 112b may be symmetrical to each other in relation to the interconnection member 115, which may be much easier in controlling warpage.

FIG. 24 is a cross-sectional view schematically illustrating another example of a fan-out semiconductor package.

Referring to FIG. 24, a fan-out semiconductor package 100G according to another example may be a wafer level package (WLP) type. That is, the fan-out semiconductor package 100G according to another example may not include the interconnection member 115 disposed on the interconnection member 130 and having the through-hole. The fan-out semiconductor package 100G may also be a package-on-package (PoP) type in which through-wirings (not illustrated) penetrating through the encapsulant 110 is formed, if necessary. The other components are the same as the components as described above.

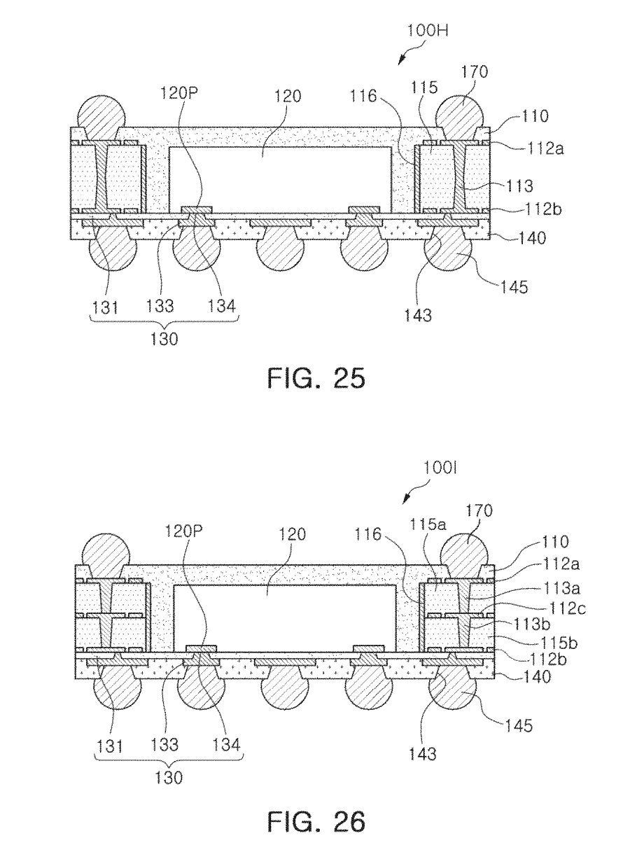

FIG. 25 is a cross-sectional view schematically illustrating a modified example of a semiconductor package according to an example.

Referring to FIG. 25, a redistribution layer 112b formed on a lower surface of the interconnection member 115 may be embedded in the interconnection member 115 so that one surface thereof is exposed. In this case, a thickness of the redistribution layer 112b formed on the lower surface of the interconnection member 115 may be ignorable. Therefore, a fine pitch may be implemented. The other components are the same as the components as described above.

FIG. 26 is a cross-sectional view schematically illustrating a modified example of a semiconductor package according to an example.

Referring to FIG. 26, interconnection members 115a and 115b may be formed of multiple layers. In this case, a redistribution layer 112c may also be disposed in the interconnection members 115a and 115b. The redistribution layer 112c disposed in the interconnection members 115a and 115b may be electrically connected to redistribution layers 112a and 112b disposed at both sides of the interconnection members 115a and 115b through vias 113a and 113b. In this case, the number of layers of the interconnection member 130 may be reduced. In addition, a degree of freedom of a design of the interconnection member 130 may be increased. Further, a process defect occurring at the time of manufacturing the interconnection member 130 may be reduced, and thus a yield may be improved. The other components are the same as the components as described above.

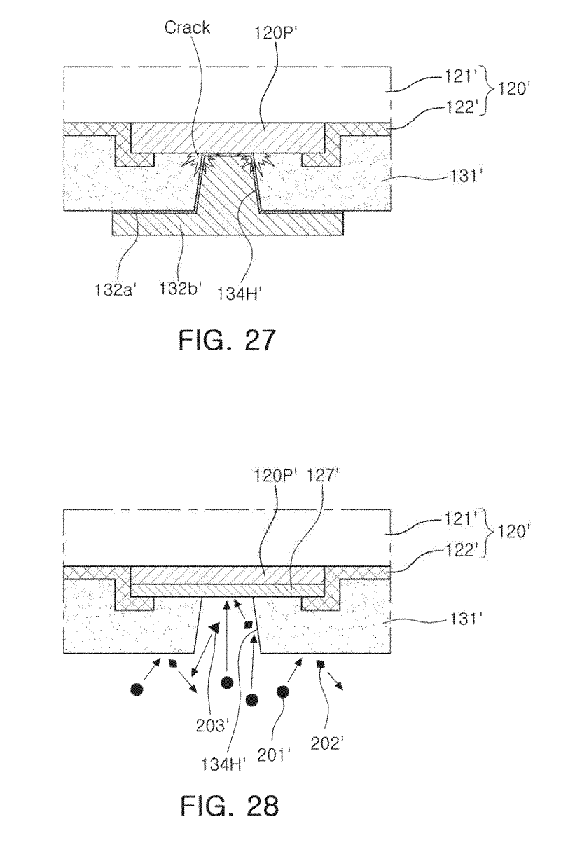

FIG. 27 is a view schematically illustrating a case in which a crack is generated between an electrode pad of an electronic component and a via of an interconnection member.

Referring to FIG. 27, an electronic component 120′ may include a body 121′, a passivation layer 122′, and an electrode pad 120P′. In addition, an insulating layer 131′ may be disposed on one side of the electronic component 120′, and a via hole 134H′ penetrating through the insulating layer 131′ may open at least a portion of the electrode pad 120P′. A seed layer 132a′ for a conductive via, or the like, may be disposed on a surface of the electrode pad 120P′ exposed by the via hole 134H′, and a conductor layer 132b′ may be disposed on the seed layer 132a′. Meanwhile, the electrode pad 120P′ may generally contain aluminum (Al), the seed layer 132a′ may contain titanium (Ti), and the conductor layer 132b′ may contain copper (Cu). Here, since a difference between coefficients of thermal expansion (CTEs) of aluminum (Al), titanium (Ti), and copper (Cu) is significantly large, in a case in which stress is concentrated on the via, a TC failure such as a crack or interfacial delamination may be easily generated due to weak adhesion.

FIG. 28 is a view schematically illustrating a case in which an organic etching material remains on a surface of an electrode pad of an electronic component.

Referring to FIG. 28, an electronic component 120′ may include a body 121′, a passivation layer 122′, and an electrode pad 120P′. A natural oxide layer 127′ may be formed on a surface of the electrode pad 120P′. An insulating layer 131′ may be disposed on one side of the electronic component 120′, and a via hole 134H′ penetrating through the insulating layer 131′ may open at least a portion of the electrode pad 120P′. Before a conductive via is formed in the via hole 134H′, the natural oxide layer 127′ formed on the surface of the electrode pad 120P′ may be removed through plasma pre-processing using argon (Ar) particles 201′, or the like. Here, in a process of removing the natural oxide layer 127′ through the plasma pre-processing, or the like, decomposed materials 203′ of the natural oxide layer 127′ or an organic material of the insulating layer 131′ and moisture 202′ may pollute the electrode pads 120P′. As a result, these pollutants may be present on an interface between a seed layer of a via formed subsequently and the electrode pad 120P′, such that adhesion between the via and the electrode pad may be reduced.

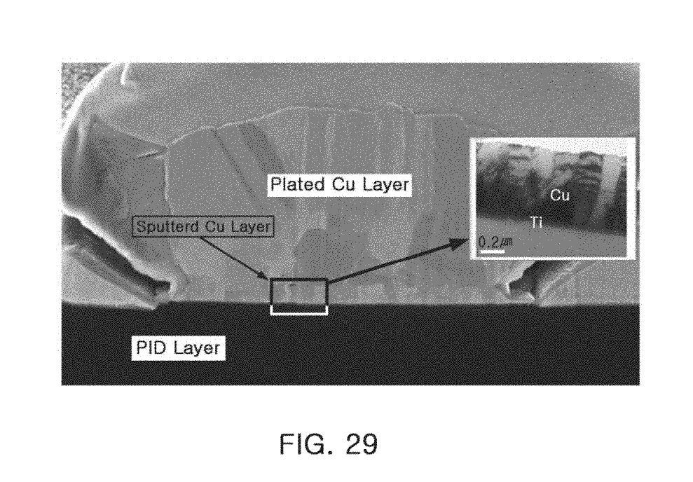

FIG. 29 is a photograph of microstructures of copper (Cu) layers formed by electroplating and sputtering.

Referring to FIG. 29, it may be confirmed that a difference is present between microstructures of copper (Cu) layers formed in an electroplating scheme and a sputtering scheme depending on a deposition scheme. The microstructure of the copper (Cu) layer formed in the sputtering scheme may have a columnar shape. On the other hand, the microstructure of the copper (Cu) layer formed in the electroplating scheme may have an irregular shape. Therefore, a boundary between the copper (Cu) layer formed in the electroplating scheme and the copper (Cu) layer formed in the sputtering scheme may be distinguishable, and materials and thicknesses of these copper (Cu) layers, and methods of forming these copper (Cu) layers may be analyzed through structures.

As set forth above, according to an exemplary embodiment in the present disclosure, a fan-out semiconductor package in which reliability of the via of the interconnection member is improved, and a method of manufacturing the same may be provided.

In the present disclosure, a word “connected” is a concept including a case in which any component is indirectly connected to another component by an adhesive, or the like, as well as a case in which any component is directly connected to another component. In addition, a word “electrically connected” is a concept including both of a case in which any component is physically connected to another component and a case in which any component is not physically connected to another component.

In the present disclosure, terms “first”, “second”, and the like, are used to distinguish one component from another component, and do not limit a sequence, importance, and the like, of the corresponding components. In some cases, a first component may be named a second component and a second component may also be similarly named a first component, without departing from the scope of the present disclosure.

A term “example” used in the present disclosure does not mean the same exemplary embodiment, but is provided in order to emphasize and describe different unique features. However, the above suggested examples may be implemented to be combined with a feature of another example. For example, even though particulars described in a specific example are not described in another example, it may be understood as a description related to another example unless described otherwise.

Terms used in the present disclosure are used only in order to describe an exemplary embodiment rather than limiting the present disclosure. Here, singular forms include plural forms unless interpreted otherwise in a context.

While exemplary embodiments have been shown and described above, it will be apparent to those skilled in the art that modifications and variations could be made without departing from the scope of the present invention as defined by the appended claims.

What is claimed is:

1. A fan-out semiconductor package comprising:
a semiconductor chip including a body and an electrode pad disposed on the body;
a metal layer disposed on the electrode pad of the semiconductor chip and covering at least a portion of the electrode pad; and
an interconnection member including an insulating layer disposed on one side of the semiconductor chip, a via hole penetrating through the insulating layer and exposing at least a portion of a surface of the metal layer covering the electrode pad, a seed layer disposed on the surface of the metal layer exposed by the via hole and a wall of the via hole, and a conductor layer disposed on the seed layer.

2. The fan-out semiconductor package of claim 1, wherein the metal layer includes:
an interlayer seed layer disposed on the electrode pad; and
an interlayer conductor layer disposed on the interlayer seed layer.

3. The fan-out semiconductor package of claim 2, wherein the conductor layer and the seed layer of the interconnection member are conterminous with each other, and the interlayer conductor layer and the interlayer seed layer of the metal layer are conterminous with each other.

4. The fan-out semiconductor package of claim 3, wherein an area of the interlayer conductor layer exposed by the via hole of the interconnection member is not equal to an area of the interlayer conductor layer.

5. The fan-out semiconductor package of claim 2, wherein the interlayer seed layer of the metal layer contains the same material as that of the seed layer of the interconnection member, and
the interlayer conductor layer of the metal layer contains the same material as that of the conductor layer of the interconnection member.

6. The fan-out semiconductor package of claim 5, wherein the interlayer seed layer contains one or more of titanium (Ti), titanium-tungsten (Ti—W), molybdenum (Mo), chrome (Cr), nickel (Ni), and nickel-chrome (Ni—Cr).

7. The fan-out semiconductor package of claim 5, wherein the interlayer conductor layer of the metal layer includes a first interlayer conductor layer disposed on the seed layer and containing copper (Cu).

8. The fan-out semiconductor package of claim 7, wherein the interlayer conductor layer of the metal layer further includes a second interlayer conductor layer disposed on the first interlayer conductor layer thereof and containing copper (Cu).

9. The fan-out semiconductor package of claim 5, wherein the seed layer of the interconnection member includes a first seed layer disposed on a surface of the interlayer conductor layer of the metal layer and the wall of the via hole and containing one or more of titanium (Ti), titanium-tungsten (Ti—W), molybdenum (Mo), chrome (Cr), nickel (Ni), and nickel-chrome (Ni—Cr); and
a second seed layer disposed on the first seed layer and containing copper (Cu).

10. The fan-out semiconductor package of claim 5, wherein the conductor layer contains copper (Cu).

11. The fan-out semiconductor package of claim 1, wherein the semiconductor chip further includes a passivation layer disposed on the body and covering a portion of the electrode pad.

12. The fan-out semiconductor package of claim 11, wherein the metal layer contacts the passivation layer, and
only a portion of the surface of the metal layer is exposed by the via hole.

13. The fan-out semiconductor package of claim 11, wherein the metal layer is partially disposed on the passivation layer, and
only a portion of the surface of the metal layer is exposed by the via hole.

14. The fan-out semiconductor package of claim 11, wherein the metal layer is spaced apart from the passivation layer, and
only a portion of the surface of the metal layer is exposed by the via hole.

15. The fan-out semiconductor package of claim 11, wherein the metal layer is spaced apart from the passivation layer, and
an entire surface of the metal layer is exposed by the via hole.

16. The fan-out semiconductor package of claim 1, wherein the body contains one or more of silicon (Si), germanium (Ge), and gallium arsenide (GaAs).

17. The fan-out semiconductor package of claim 1, wherein the electrode pad contains aluminum (Al).

18. The fan-out semiconductor package of claim 1, wherein the semiconductor chip further includes a passivation layer disposed on the body and covering a first portion of a surface of the electrode pad and exposing a second portion of the surface of the electrode pad, and
the metal layer contacts the second portion of the surface of the electrode pad and is physically spaced apart from the first portion of the surface of the electrode pad.
